(19) United States
(12) Patent Application Publication
(10) Pub. No.: US 2009/0175022 A1
(43) Pub. Date: Jul. 9, 2009

(54) MULTI-LAYER PACKAGE STRUCTURE AND FABRICATION METHOD THEREOF

(75) Inventors: Young-Se Kwon, Daejeon (KR); Jon-Min Yook, Daejeon (KR)

Correspondence Address: GIFFORD, KRASS, SPRINKLE,ANDERSON & CITKOWSKI, P.C, PO BOX 7021, TROY, MI, 48007-7021, US

(73) Assignees: Wavenics Inc., Daejeon (KR); Korea Advanced Institute of Science and Technology, Daejeon (KR)

(21) Appl. No.: 12/281,516

(22) PCT Filed: Jun. 15, 2006
(86) PCT No.: PCT/KR2006/002285

§ 371 Date: Jan. 5, 2009

(30) Foreign Application Priority Data
Mar. 3, 2006 (KR) 10-2006-0020636

(51) Int. Cl. H05K 5/02; H01R 12/00; H01R 43/00

(52) U.S. Cl. 361/820; 174/261; 29/879

(57) ABSTRACT

A method for allowing an easier electric connection between layers of a multi-layer package structure using a metal pin fabricated based on semiconductor device processes is provided. A metal pin having a high aspect ratio is formed on a lower substrate, while a via hole is formed in an upper substrate. The metal pin is inserted into the via hole and adhered together to make an electric connection between the lower and upper substrates. The metal pin is obtained by patterning a thick photoresist material and plating a material thereon. The metal pin may have a core member obtained by performing a plating process on the surface of a patterned polymer based pin. Solder or gold is used for adhesion and electric connection between the signal line and the metal pin. The above electric connection method can be simpler and have improved structural stability compared with the typical connection method.

### TECHNICAL FIELD

The present invention relates to packaging of a semiconductor device, and more particularly, to a multi-layer package structure using a metal pin with a high aspect ratio and a fabrication method thereof.

### BACKGROUND ART

Among numerous semiconductor device manufacturing processes, packaging is implemented to protect semiconductor chips from external environmental conditions, to form the semiconductor chips in a certain shape to be used conveniently and to protect designed operations of the semiconductor chips. As a result, packaging can improve reliability of a semiconductor device.

As semiconductor devices are becoming highly integrated and being designed to have various functions, packaging is being shifted toward using the increasing number of pins and implementing a surface mounting scheme instead of inserting the package into a printed circuit board (PCB). Many packages implemented with the surface mounting scheme, e.g., a small outline package (SOP), a plastic leaded chip carrier (PLCC), a quad flat package (QFP), a ball grid array (B GA), and a chip scale package (CSP), are being introduced.

One required technology for manufacturing smaller and lighter electronic devices is to integrate chips or wires within a limited small area. One suggested method is to package semiconductor chips and wires in multiple layers.

According to this typical multi-layer packaging method, a plurality of via holes are formed on at least one of top layers stacked over a base layer. A conductive material fills the via holes and are electrically connected with signal lines, formed above or underneath the conductive material, using a stud or solder.

However, the above connection method often does not give a desired level of electric connection between the conductive material and the signal lines due to outspread and slippery bumpers. Also, this connection method may be complicated and may not be cost-effective. Since the conductive material can be connected with the signal lines using an adhesive interposed therebetween, structural stability may be reduced.

### DISCLOSURE OF INVENTION

### Technical Problem

Therefore, one embodiment of the present invention is directed to provide a multi-layer package structure that can be cost-effective by allowing an easy electric connection between multiple layers of stacked chips, and a fabrication method thereof.

Another embodiment of the present invention is directed to provide a multi-layer package structure that can improve an electric connection between target elements, often being degraded by an outspread and slippery bumper when the target elements are electrically connected using a typical solder bumper, and a fabrication method thereof.

Another embodiment of the present invention is directed to provide a multi-layer package structure that can have structural stability by fixing at least one of top layers with an adhesive and a metal pin, and a fabrication method thereof.

### Technical Solution

According to one embodiment of the present invention, there is provided a multi-layer package structure, including: a first substrate including: a first signal line formed on the first substrate; and at least one metal pin connected with the first signal line and having a high aspect ratio; a second substrate stacked on the first substrate and including: a second signal line formed on the second substrate; and at least one via hole into which the metal pin of the first substrate is inserted; and a connecting member (or a solder unit) connecting the metal pin inserted into the via hole with the second signal line.

The metal pin may include a supporting member being conductive and formed on the first signal line, and the connecting member formed on the supporting member.

The metal pin may include a core member disposed on the first signal line and formed of a polymer material, and a connecting member plated on an outer surface of the core member.

The supporting member or the core member may be formed in a step structure.

The second signal line may include a bumper formed in a predetermined region where the via hole is to be formed.

The first substrate may further include an alignment pattern to be aligned with the second substrate, and the second substrate may further include another via hole passing through the second substrate and into which the alignment pattern is inserted.

According to another embodiment of the present invention, there is provided a multi-layer package structure, including: a first substrate including: a first signal line formed on the first substrate; and at least one first metal pin connected with the first signal line and having a high aspect ratio; a second substrate stacked on the first substrate and including: a second signal line formed on the second substrate; at least one first via hole into which the first metal pin of the first substrate is inserted; and at least one second metal pin disposed above the first via hole; a third substrate stacked on the second substrate and including: a third signal line formed on the third substrate; and at least one second via hole through which the second metal pin of the second substrate is inserted; and connecting members (or solder units) connecting the first and second metal pins inserted respectively into the first and second via holes with the second and third signal lines, respectively.

The first substrate and the second substrate may include indentations to mount devices including a micro electro mechanical system (MEMS) and an integrated circuit (IC).

The first metal pin of the first substrate may be formed in a step structure. The first metal pin may include a first portion contacting a bottom surface of the second substrate to support the second substrate, a second portion formed on the first portion with a smaller area than the first portion, and a connecting member formed on the second portion. The first substrate may further include devices including devices a MEMS and an IC mounted on the first substrate within spaces of the first substrate defined by the first portion of the first metal pin.

The first substrate may further include an alignment pattern to be aligned with the second substrate. The second substrate may further include another via hole passing through the second substrate and into which the alignment pattern is inserted.

According to another embodiment of the present invention, there is provided a method for fabricating a multi-layer package structure, including: preparing a first substrate, the first substrate including: a first signal line formed on the first substrate; at least one metal pin connected with the first signal line and having a high aspect ratio; preparing a second substrate, the second substrate including: a second signal line formed on the second substrate; and at least one via hole into which the metal pin of the first substrate is inserted; inserting the metal pin of the first substrate into the via hole of the second substrate; and connecting the metal pin inserted into the via hole with the second signal line.

The connecting the metal pin with the second signal line may include inserting the metal pin that includes a solder based plating layer or a metal direct adhesion layer (e.g., a gold based layer) in an edge portion of the metal pin into the via hole, and reflowing the solder based plating layer.

The connecting the metal pin with the second signal line may include inserting the metal pin that includes a solder based plating layer in an edge portion of the metal pin into the via hole, and applying heat and pressure to the inserted metal pin to provide the connection.

The connecting the metal pin with the second signal line may include inserting the metal pin that includes a bumper formed in a predetermined region where the via hole is to be formed into the via hole, and applying heat and pressure to the bumper to provide the connection.

The metal pin may include a core member including a polymer based material, and a connecting member plated on an outer surface of the core member. The metal pin may be formed by: patterning the polymer material; roughening a surface of the polymer material through performing a plasma process; and performing a plating process using a dielectric material including silicon dioxide (SiO₂) as a mask.

The first substrate may further include the alignment pattern to be aligned with the second substrate, and the second substrate may further include another via hole passing through the second substrate and into which the alignment pattern is inserted. Prior to combining the first substrate with the second substrate, the method may further include aligning the first substrate and the second substrate with each other using an alignment pattern.

### ADVANTAGEOUS EFFECTS

According to exemplary embodiments of the present invention, an electric connection method between multiple layers using a metal pin is simpler than the typical electric connection method using a bumper (e.g., a stud or solder) after a metal based material fills via holes. Therefore, a multi-layer package structure can be fabricated with cost-effectiveness, and when the multiple layers are stacked over each other using the metal pin, the metal pin can give a firm fixation (or support) to the resultant structure. As a result, structural stability of the multi-layer package structure can be achieved.

### BRIEF DESCRIPTION OF THE DRAWINGS

The above text and features of the present invention will become better understood with respect to the following description of the exemplary embodiments given in conjunction with the accompanying drawings, in which:

FIGS. 1 to 3 are cross-sectional views respectively illustrating a lower substrate structure with metal pins, which are formed of a conductive material and have a high aspect ratio, a lower substrate structure with metal pins, which uses a polymer material as a core member and a high aspect ratio, and a lower substrate structure with metal pins, which have a high aspect ratio and are formed in a step structure by repeating predetermined processes twice;

FIGS. 4 and 5 are cross-sectional views illustrating upper substrate structures with via holes into which the metal pins of the lower substrate structure illustrated in FIGS. 1 to 3 are to be inserted;

FIGS. 6 and 7 are cross-sectional views illustrating connecting members for an electric connection when the upper substrate structure and the lower substrate structure are combined together according to an embodiment of the present invention;

FIGS. 8 and 9 are cross-sectional views illustrating connecting members for an electric connection when the upper substrate structure and the lower substrate structure are combined together according to another embodiment of the present invention;

FIG. 10 is a cross-sectional view illustrating connecting members for an electric connection when the upper substrate structure and the lower substrate structure are combined together according to another embodiment of the present invention, and

FIGS. 11 and 12 are cross-sectional views illustrating multi-layer package modules obtained by stacking the lower substrate structure with the metal pins illustrated FIG. 1 or FIG. 3 and the upper substrate structure with the via holes illustrated in FIG. 4 in triple layer structures.

### BEST MODE FOR CARRYING OUT THE INVENTION

Various embodiments of the present invention will be described in detail with reference to the accompanying drawings.

FIGS. 1 to 3 are cross-sectional views illustrating lower substrate structures with different types of metal pins according to an embodiment of the present invention.

Referring to FIG. 1, the lower substrate structure 100 includes a base substrate 2 on which an electric signal line 4 (hereinafter referred to as “signal line”) is formed, and metal pins 10 formed over the base substrate 2 and having a high aspect ratio. Each of the metal pins 10 includes a supporting member 6 and a connecting member 8. In more detail of the formation of the metal pins 10, a metal layer is plated on the base substrate 2 on which the electric signal line 4 is formed. Thereafter, a thick photoresist film is coated on the base substrate 2 including the signal line 4 and patterned to expose a plate region. The metal layer of the exposed portion is plated with copper to form the supporting members 6 of the metal pins 10. Afterwards, nickel and solder (or gold) are sequentially plated on the copper-plated portion to form the connecting members 8 of the metal pins 10. As illustrated in FIG. 1, the metal pins 10 have a high aspect ratio.

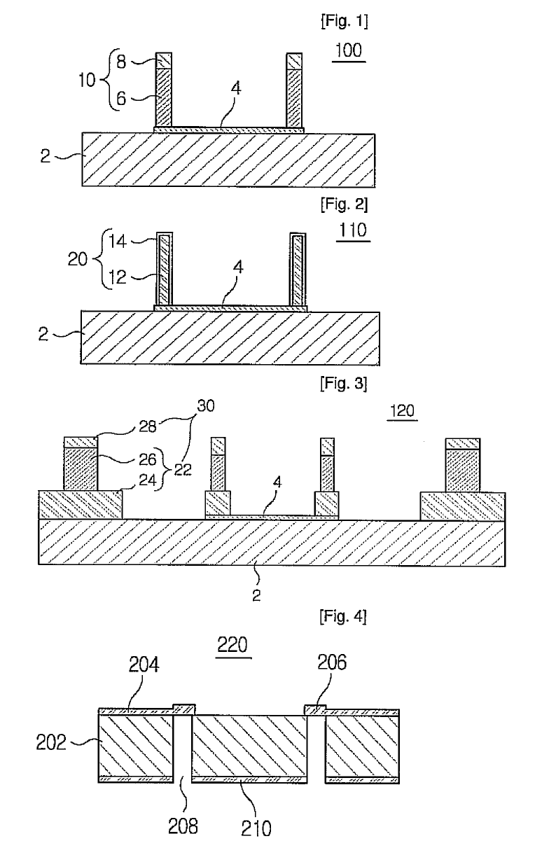

FIG. 2 illustrating a modified metal pin structure using a polymer material as a core member.

Referring to FIG. 2, the lower substrate structure 110 includes a base substrate 2 on which a signal line 4 is formed, and metal pins 20. Each of the metal pins 20 includes a core member 12 formed using a polymer material, and a connecting member 14 formed on the outer surface of the core member 12.

In more detail of the formation of the metal pins 20, a pin structure is formed using a thick polymer material that can be patterned, and the surface of the polymer material is made rough using a plasma, and a metal layer is coated on the entire surface of the resultant structure using a sputter coating method. According to this method, the metal layer can be coated on the entire surface of the polymer material of which surface is made rough. An insulation mask material such as silicon dioxide (SiO₂) is formed, and afterwards, copper, nickel, and solder or gold are plated thereon. This plating takes place selectively on the roughened surface of the polymer material, and the resultant metal pins 20 are illustrated in FIG. 2.

FIG. 3 illustrates the lower substrate structure 120 with another modified metal pins 30. The supporting members 6 of the metal pins 10 illustrated in FIG. 1 are formed in a step structure. Each of the step structured supporting members 22 of the lower substrate structure 120 includes a first portion 24 and a second portion 26.

The lower substrate structure 120 illustrated in FIG. 3 is obtained by repeatedly performing the fabrication method described in FIG. 1. In more detail of forming the metal pins 30 in a step structure, the patterning is performed twice using a photoresist film (PR) and copper is plated thickly on the patterned regions to form the first and second portions 24 and 26 of the supporting members 22. Afterwards, nickel and solder or gold are sequentially plated to form connecting members 28.

The step structure can be implemented to a method of repeatedly fabricating a metal pin having a polymer material as a core member, a method of combining a structure based purely on metal with a metal structure having a polymer material as a core member, and to a method of forming a first portion of a supporting member using a dielectric material.

In the case of using the dielectric material as the first portion 24 of the supporting member 26 as illustrated in FIG. 3, a metal layer is formed on the dielectric material 24 and patterned using a photoresist film. Afterwards, a plating process is performed to form the second portion 26 of the supporting member 22, and the connecting member 28.

FIG. 4 is a cross-sectional view illustrating an upper substrate structure 220 where bonding bumpers and via holes are formed.

As illustrated, the upper substrate structure 220 is fabricated as follows. Another signal line 204 is formed on another base substrate 202, and a metal layer for plating is formed over the other base substrate 202. Through patterning and plating processes, bumpers 206 are formed on predetermined regions of the other base substrate 202 where via holes are to be formed to apply heat and pressure during a bonding process. As mentioned above, the via holes allow an electric connection between an upper layer and a lower layer during the bonding process. After these sequential processes are completed, the other base substrate 202 is inverted to form the aforementioned via holes 208 in predetermined regions corresponding to the bumpers 206. Particularly, the via holes 208 are formed using a plasma or chemical etching method. If necessary, an epoxy layer 210 for adhesion may be formed on the inverted surface of the other base substrate 202 using a screen printing method or a dispenser.

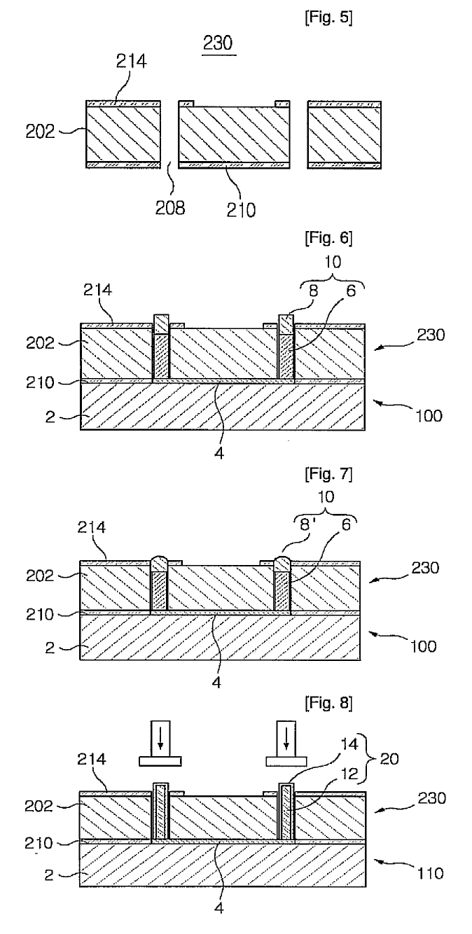

FIG. 5 illustrates an upper substrate structure 230 through which via holes 208 pass without bumpers 206 illustrated in FIG. 4. The upper substrate structure 230 illustrated in FIG. 5 is fabricated as follows. Similar to the fabrication method described in FIG. 4, another signal line 214 is formed on another base substrate 202, and the other base substrate 202 is inverted to form the via holes 208 that pass through the other base substrate 202. Particularly, the via holes 208 are formed using a chemical etching method, or a mechanical method using a laser or a mechanical drill. If necessary, an epoxy layer 210 may be formed on the inverted surface of the other base substrate 202.

FIGS. 6 and 7 illustrate multi-layer package structures for electric connection according to an embodiment of the present invention. Particularly, the multi-layer package structures are obtained by stacking the lower substrate structure 100 and the upper substrate structure 230 fabricated based on the methods described in FIG. 1 and FIG. 5, respectively.

Referring to FIG. 6, the lower substrate structure 100 on which the metal pins 10 are formed and the upper substrate structure 230 in which the via holes 208 are formed are aligned with each other. The lower substrate structure 100 is inserted into the upper substrate structure 230, and if necessary, pressure is applied thereto to make the lower substrate structure 100 and the upper substrate structure 230 adhered easily through the epoxy layer 210. At this point, the metal pins 10 should be higher than the via holes 208 to make the connecting members 8 (i.e., the solder portions) protrude outward.

A reflow process is performed on the protruded connecting members 8 to change the original shape of the connecting members 8 into a ball shape. This changed shape of the connecting members 8 is illustrated in FIG. 7, and the ball shaped connecting members are denoted with reference numeral 8′. This shape change results in an electric connection with the other signal line 214.

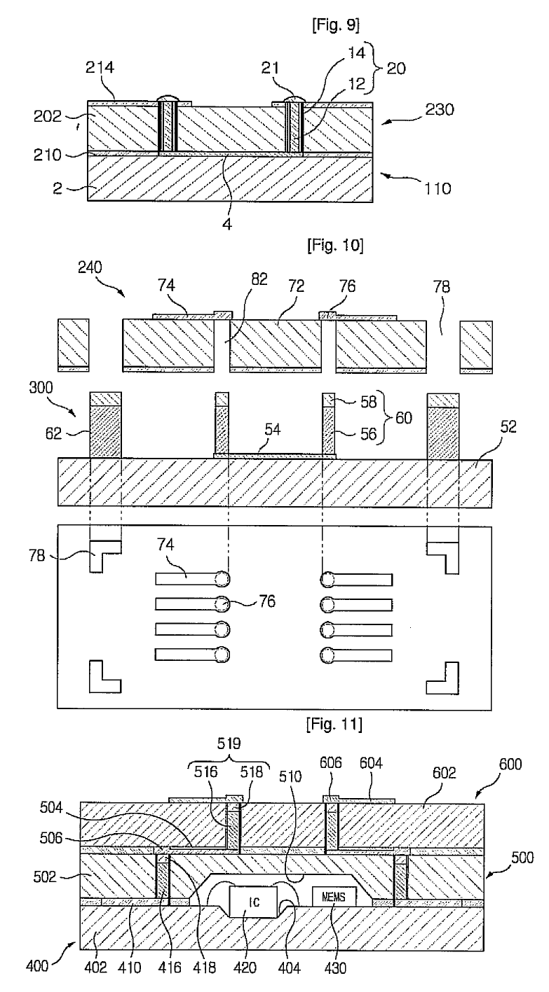

FIGS. 8 and 9 illustrate multi-layer package structures using a modified electric connection method from the electric connection method described in FIGS. 6 and 7. Particularly, heat and mechanical force are applied to metal direction adhesion layers (e.g., the solder or gold based layers), and as a result, an electric adhesion can be achieved. This modified electric connection method can be applied to the metal pins 10, 20 and 30 illustrated in FIGS. 1 to 3, and particularly, may be effective for the metal pins 20 illustrated in FIG. 2.

As similar to the above described electric connection method, this modified electric connection method allows the electric connection between the metal pins 20 and peripheral electrodes by performing sequential operations. More specifically, the metal pins 20 that include a polymer material as the core members 12 are aligned with the via holes 208 and then, inserted into the via holes 208. Afterwards, heat and mechanical pressure are applied to edge portions of the protruded metal pins 20, so that the electric connection can be achieved.

FIG. 10 illustrates a multi-layer package structure using another connection method according to another embodiment of the present invention. The multi-layer package structure is obtained using a upper substrate structure 240 that has substantially the same structure illustrated in FIG. 4 and a lower substrate structure 300 that has substantially the same structure illustrated in FIG. 1. When the upper and lower substrate structures 240 and 300 are aligned with each other, metal pins 60 of the lower substrate structure 300 are not often seen. Thus, the lower substrate structure 300 further includes an alignment pattern 62 to align the upper and lower substrate structures 240 and 300. Via holes 78 into which the alignment pattern 62 is inserted are formed to pass through the upper substrate structure 240, and thus, the alignment pattern 62 can be seen from the via holes 78. The alignment pattern 62 can be used not only to combine the upper substrate structure 240 with the lower substrate structure 300, but also to stably support the combined upper and lower substrate structures 240 and 300. When heat and pressure are applied to upper edge portions of the upper substrate structure 240, the applied beat and pressure are transferred to the metal pins 60 from upper bumpers 76 of another via holes 82 into which the metal pins 60 are inserted. As a result, connecting members 58 of the metal pins 60 are melted to make an electric connection between a signal line 74 of the upper substrate structure 240 and the corresponding metal pins 60 of the lower substrate structure 300.

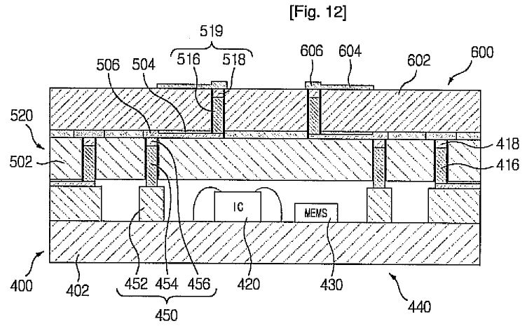

FIGS. 11 and 12 illustrate exemplary triple layer package structures using the other electric connection method described in FIG. 10.

Referring to FIG. 11, indentations 404 and 510 are formed respectively in a lower substrate structure 400 and a first upper substrate structure 500 to mount a micro electro mechanical system (MEMS) 430 and an integrated circuit (IC) 420 on the lower substrate structure 400. Referring to FIG. 12, a lower substrate structure 400 is designed to have the metal pin structure illustrated in FIG. 3, and thus, spaces are generated between layers. Within these spaces, an MEMS 430 and an IC 420 are mounted.

More specifically, in FIG. 12, first metal pins 450 are formed in a step structure. Each of the first metal pins 450 includes a first portion 452, a second portion 454 and a solder portion 456. The first portion 452 is disposed below the bottom surface of a first upper substrate structure 520 to support the first upper substrate structure 520. The second portion 454 is formed on the first portion 452 by haying a smaller area than the first portion 452. The solder portion 456 is formed on the second portion 454.

The first upper substrate structure 520 includes second metal pins 519 formed on the first supper substrate structure 520 to make an electric connection with a second upper substrate structure 600 stacked over the first upper substrate structure 520. The second metal pins 519 are inserted into via holes formed in corresponding regions of the second upper substrate structure 600.

Although the exemplary embodiments of the present invention are described with reference to the accompanying drawings, the present invention should not construed as being limited to the provided exemplary embodiments and the drawings, and it will be understood by those of ordinary skill in the art that various changes in form and details may be made without departing from the spirit and scope of the present invention.

1. A multi-layer package structure comprising:
a first substrate including a first signal line formed thereon and at least one metal pin connected with the first signal line and having a high aspect ratio;
a second substrate stacked on the first substrate and including a second signal line formed on the second substrate and at least one via hole into which the metal pin of the first substrate is inserted; and
a connecting member connecting one end of the metal pin inserted into the via hole with the second signal line,
wherein the connecting member is a solder or a direct bonding between metals solder unit and a direct bonding between metals.

2. The multi-layer package structure of claim 1, wherein the metal pin comprises:
a conductive supporting member formed on the first signal line; and
the connecting member formed on the conductive supporting member.

3. The multi-layer package structure of claim 1, wherein the metal pin comprises:
a core member disposed on the first signal line and formed of a polymer material; and
a connecting member plated on an outer surface of the core member.

4. The multi-layer package structure of claim 2, wherein one of the conductive supporting member and the core member is formed in a step structure.

5. The multi-layer package structure of claim 2, wherein one of the conductive supporting member and the core member is formed in a step structure, and a bottom portion of the step structure includes a dielectric material.

6. The multi-layer package structure of claim 1, wherein the second signal line comprises a bumper formed in a predetermined region where the via hole is to be formed.

7. The multi-layer package structure of claim 1, wherein the first substrate further comprises an alignment pattern to be aligned with the second substrate, and the second substrate further comprises another via hole passing through the second substrate and into which the alignment pattern is inserted.

8. The multi-layer package structure of claim 1, wherein the metal pin of the first substrate is formed in a step structure and includes:
a first portion contacting a bottom surface of the second substrate to support the second substrate;
a second portion formed on the first portion with a smaller area than the first portion; and
a connecting member formed on the second portion.

9. A multi-layer package structure comprising:
a first substrate including a first signal line formed thereon and at least one first metal pin connected with the first signal line and having a high aspect ratio;
a second substrate stacked on the first substrate and including a second signal line formed on the second substrate, at least one first via hole into which the first metal pin of the first substrate is inserted, and at least one second metal pin disposed above the first via hole;
a third substrate stacked on the second substrate and including a third signal line formed on the third substrate and at least one second via hole through which the second metal pin of the second substrate is inserted; and
connecting members connecting the first and second metal pins inserted respectively into the first and second via holes with the second and third signal lines, respectively.

10. The multi-layer package structure of claim 9, wherein the first substrate and the second substrate comprise indentations to mount one of a surface mount device (SMD) and a semiconductor device on the first substrate, the semiconductor device including a micro electro mechanical system (MEMS) and an integrated circuit (IC).

11. The multi-layer package structure of claim 9, wherein the first substrate further comprises one of a semiconductor device and a SMD mounted on the first substrate within spaces of the first substrate defined by a first portion of the first metal pin.

12. The multi-layer package structure of claim 8, wherein the first portion comprises a dielectric material.

13. The multi-layer package structure of claim 10, wherein the first substrate further comprises an alignment pattern to be aligned with the second substrate, wherein the second substrate further includes another via hole passing through the second substrate and into which the alignment pattern is inserted.

14. A method for fabricating a multi-layer package structure, the method comprising:
preparing a first substrate, the first substrate including a first signal line formed on the first substrate, and at least one metal pin connected with the first signal line and having a high aspect ratio;
preparing a second substrate, the second substrate including a second signal line formed on the second substrate and at least one via hole into which the metal pin of the first substrate is inserted;
inserting the metal pin of the first substrate into the via hole of the second substrate; and
connecting the metal pin inserted into the via hole with the second signal line.

15. The method of claim 14, wherein the connecting the metal pin with the second signal line comprise:
inserting the metal pin that includes a solder based plating layer in an edge portion of the metal pin into the via hole; and
reflowing the solder based plating layer.

16. The method of claim 14, wherein the connecting the metal pin with the second signal line comprises:
inserting the metal pin that includes a bumper formed in a predetermined region where the via hole is to be formed into the via hole; and
applying heat and pressure to the bumper.

17. The method of claim 14, wherein the metal pin comprises a core member including a polymer based material, and a connecting member plated on an outer surface of the core member,
wherein the metal pin is formed by: patterning the polymer material; roughening a surface of the polymer material through performing a plasma process; and performing a plating process using a dielectric material including silicon dioxide (SiO₂) as a mask.

18. The method of claim 14, prior to combining the first substrate with the second substrate, further comprising aligning the first substrate and the second substrate with each other using an alignment pattern, wherein the first substrate further includes the alignment pattern to be aligned with the second substrate, wherein the second substrate further includes another via hole passing through the second substrate and into which the alignment pattern is inserted.
